(19) United States
(12) Patent Application Publication
(10) Pub. No.: US 2010/0013509 A1
(43) Pub. Date: Jan. 21, 2010

(54) PROBER AND SEMICONDUCTOR WAFER TESTING METHOD USING THE SAME

(75) Inventors: Shota SETOGUCHI, Yokohama-shi (JP); Yosuke KAWAMATA, Tokyo (JP)

Correspondence Address: YOUNG & THOMPSON, 209 Madison Street, Suite 500, Alexandria, VA, 22314, US

(73) Assignees: ELPIDA MEMORY, INC., TOKYO (JP); TERA PROBER, INC., YOKOHAMA-SHI (JP)

(21) Appl. No.: 12/502,286

(22) Filed: Jul. 14, 2009

(30) Foreign Application Priority Data
Jul. 16, 2008 (JP) P2008-184969

(51) Int. Cl. G01R 31/02

(52) U.S. Cl. 324/760

(57) ABSTRACT

A prober for a semiconductor wafer test includes a stage, a probe card, and an adjuster The stage has a first region and a second region other than the first region The first region is covered by a wafer on which a plurality of electrode pads is provided. The probe card includes a plurality of probe pins to be in contact with the plurality of electrode pads. The adjuster is included in the stage and adjusts a temperature of the wafer and the second region.

### BACKGROUND OF THE INVENTION

1. Field of the Invention

The present invention relates to a prober used for a semiconductor wafer test and a semiconductor wafer testing method using the prober.

Priority is claimed on Japanese Patent Application No. 2008-184969, filed Jul. 16, 2008, the content of which is incorporated herein by reference.

2. Description of the Related Art

Generally, multiple chips are formed by processing a generally circular semiconductor wafer in a process of manufacturing a semiconductor device. After electric characteristics of each chip formed in this manner are tested, the wafer is diced into multiple pieces of the chips. Then, each chip is wire-bonded onto lead frames, and thereby a semiconductor device is formed. In this case, a semiconductor wafer testing apparatus including a prober and a tester is used for testing electric characteristics of each chip. The prober can detect electric characteristics of each chip by placing a wafer to be tested on a stage and then contacting probe pins onto electrode pads on each chip. The tester supplies power and various test signals to each chip through terminals connected to the probe pins, analyzes signals output to electrode pads of each chip, and thereby tests whether or not each chip is defective. Then, defective chips are removed.

The probe pins are arranged on a probe card so as to correspond to an arrangement of electrode pads on the semiconductor chip to be tested. When a wafer is placed on the stage, the prober detects positions of electrode pads on each chip using an alignment camera included in the prober and horizontally moves the stage so that the arrangement direction of the electrode pads corresponds to that of probe pins. Then, the positions of the electrode pads are adjusted to be below the corresponding probe pins. Then, the stage is vertically (upwardly) moved to contact the electrode pads onto the probe pins, thus a probing is carried out.

After the electrode pads contact the probe pins, power and various test signals are supplied from the tester to each chip through terminals connected to the probe pins. Then, the tester analyzes signals output to the electrodes of the chip to test whether or not the chip is defective, and thereby an electric characteristics test ends. Such an electric characteristics test is carried out multiple times at different test temperatures in consideration of actual environments in which chips are used. Since a temperature for a wafer test is determined by that of the stage, a heater or a refrigerant pipe is provided in the stage to adjust and control the temperature.

As a prober including a temperature adjustor provided in a stage, Japanese Patent Laid-Open Publication No. 2002-198405 discloses a prober including: a stage on which a wafer is to be placed; a probe card to be placed above the stage; inlet holes provided in the stage; an inlet fan that takes outside air into the inlet holes; an X-Y driver that moves the stage; a wafer provider that provides a wafer on the stage; a controller that controls the wafer provider and the X-Y driver; and an exhaust fan that is provided in the controller and releases heat generated in the controller. The intake holes connect to a vacuum mechanism through the inside of the stage.

Additionally, Japanese Patent Laid-Open Publication No. 2007-157821 discloses a prober that vacuums air on a stage using a vacuum mechanism for fixing a wafer onto the stage, takes in heated or cooled air from the outside of the prober, and thereby heats or cools the stage.

Recently, the wafer test temperature explained above tends to be increased both in a low or high temperature region in consideration of actual use environments. When electric characteristics of a heated or cooled wafer are tested, the heat of the wafer is conducted to the probe card through the probe pins, causing thermal expansion of the wafer and the probe card. In this case, the difference in the thermal expansion rates between the wafer and the probe card causes the difference between a pitch of probe pins and a pitch of electrode pads, which causes misalignment of a relative position of the prober to the electrode pads compared to the relative position at room temperature. For this reason, if the conventional prober carries out the test multiple times at different temperatures ranging from a low temperature to a high temperature, the difference between a pitch of probe pins and a pitch of electrode pads occurs in the case of a test at a high or low temperature compared to a test at room temperature. Consequently, the probe pins which are in a predetermined region of the electrode pads in the case of a test at room temperature are occasionally deviated from the predetermined region in the case of a test at a high temperature, preventing precise detection of electric characteristics.

To solve this problem, Japanese Patent Laid-Open Publication No. H05-175289 discloses a prober that includes a heater provided in a probe fixing member on the bottom surface of a probe card, and sets a pitch of probe pins so as to correspond to that of electrode pads by preliminarily adjusting a temperature of the probe card just to or close to an adjusted temperature of the wafer. Accordingly, the probe pinpoints surely contact the electrode pads of each chip on the wafer, enabling a precise test even if the probe pins simultaneously contact the electrode pads in a wider region.

In any of the related art, however, the following problems arise after careful examinations by the inventor of the present invention.

As shown in FIG. 14A, a wafer 200, which is usually circular and made of a circular ingot, is placed on a circular stage 100 included in a prober. As shown in FIG 14B, probe pins 120 are provided in a probe area 121 on one surface of a probe card 110.

As shown in FIG. 15A, the stage 100 horizontally moves so that a target chip on the wafer 200 is inside the probe area 121. Then, the stage 100 vertically moves so that the probe pins 120 contact electrode pads (not shown) on the wafer 200 as shown in FIG. 15B. In this case, when chips mounted on a periphery of the wafer 200 are tested, probe pins 120 included in an outer part of the probe area 121 deviate from the stage 100 as shown in FIG. 15B.

In this case, a deviated region E (hatched region) of the probe area 121 where the probe pins 120 deviate from the stage 100 occur as shown in FIGS. 16A and 16B. The probe pins 120 included in the deviated region E are not in contact with the electrode pads on the wafer and deviated from the stage 100. Therefore, heat of the probe card 110 is released from the deviated region E. Consequently, the temperature of the probe card 110 differs from those of the stage 100 and the wafer 200, occasionally causing the difference between a pitch of the probe pins and a pitch of the electrode pads as explained above.

Additionally, the deviated region E causes an increase or decrease in the temperature of a part of the probe card 110. When the heated or cooled part of the probe pin 120 contacts the wafer 200, the temperature of the wafer 200 varies. Thus, the wafer 200 under the test has a temperature distribution, causing the difference in test temperature. In some test conditions, a difference of only 1° C. might cause large errors of measurement results. Thus, the inventor of the present invention found in the experiments that not only the change in a pitch of probe pins, but also the occurrence of a temperature distribution of the wafer 200 being tested causes larger errors of measurement results.

When the errors of the measurement results occur, even a non-defective chip targeted for the test is regarded as defective, causing a decrease in the yield of wafers. For this reason, a prober that can perform a precise test without temperatures of a stage and a wafer on the stage as well as a probe card and the entire probe area being changed has been required for a long time.

### SUMMARY

In one embodiment, there is provided a prober for a semiconductor wafer test. The prober includes a stage, a probe card, and an adjuster. The stage has a first region and a second region other than the first region. The first region is covered by a wafer on which a plurality of electrode pads is provided. The probe card includes a plurality of probe pins to be in contact with the plurality of electrode pads. The adjuster is included in the stage and adjusts a temperature of the wafer and the second region.

In another embodiment, there is provided a method of testing a semiconductor wafer. The method includes the following processes. A probe card is moved in parallel with a stage having a first region and a second region other than the first region. The semiconductor wafer covers the first region. Then, a position of a plurality of probe pins on the probe card is adjusted with respect to a position of a plurality of electrode pads on the semiconductor wafer. Then, at least one of the plurality of probe pins is contacted onto at least one of the plurality of electrode pads. At the same time, a temperature of the semiconductor wafer and the second region is adjusted.

According to the prober, even if some of the probe pins deviates from the wafer region, thermal expansion from the deviated part is prevented. Thereby, a temperature of the entire probe card can be uniformly maintained. Additionally, an occurrence of a temperature distribution of the wafer is prevented, and thereby an occurrence of measurement errors due to a change in a test temperature can be prevented.

Further, a difference in pitches between the probe pinpoints and the electrode pads does not occur. Thereby, the probe pins can surely contact the electrode pads regardless of a change in a test temperature. Therefore, a precise semiconductor wafer test is enabled.

Similarly, according to the semiconductor wafer test method using the prober, a precise semiconductor wafer test is enabled regardless of a change in a test temperature.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plane view illustrating a wafer mounted on a stage of a prober according to a first embodiment of the present invention;

FIG. 1B is a plane view illustrating a probe card viewed from a bottom surface thereof;

FIGS. 2A and 2B are lateral views illustrating a state of the prober according to the first embodiment contacting probe pins onto the wafer;

FIGS. 3A and 3B are plane views illustrating a state of the prober according to the first embodiment contacting probe pins onto the wafer;

FIG. 4 is a plane view illustrating a wafer mounted on a stage of a prober according to a second embodiment of the present invention;

FIGS. 5A and 5B are lateral views illustrating a state of the prober according to the second embodiment contacting probe pins onto the wafer;

FIGS. 6A and 6B are plane views illustrating a state of the prober according to the second embodiment contacting probe pins onto the wafer;

FIG. 7 is a lateral view illustrating the configuration of a duct included in a prober according to a third embodiment of the present invention;

FIG. 8A is a lateral view illustrating a prober according to a fourth embodiment of the present invention;

FIG. 8B is a plane view illustrating a wafer mounted on a stage of the prober according to the fourth embodiment;

FIG. 9 is a plane view illustrating a wafer mounted on a stage of a prober according to a fifth embodiment of the present invention;

FIGS. 10A and 10B are lateral views illustrating a state of the prober contacting probe pins onto the wafer according to the fifth embodiment;

FIGS. 11A and 11B are plane views illustrating a state of the prober contacting probe pins onto the wafer according to the fifth embodiment;

FIG. 12A is a lateral view illustrating a prober according to a sixth embodiment of the present invention;

FIG. 12B is a plane view illustrating a wafer mounted on a stage of the prober according to the sixth embodiment;

FIG. 13A is a lateral view illustrating a prober according to a seventh embodiment of the present invention;

FIG. 13B is a plane view illustrating a wafer mounted on a stage of the prober according to the seventh embodiment;

FIGS. 14A and 14B are plane views illustrating a conventional prober;

FIGS. 15A and 15B are lateral views illustrating the conventional prober; and

FIGS. 16A and 16B are plane views illustrating the conventional prober.

### DETAILED DESCRIPTION OF THE PREFERRED EMBODIMENTS

The invention will now be described herein with reference to illustrative embodiments. The accompanying drawings explain a prober and a semiconductor wafer testing method in the embodiments. The size, the thickness, and the like of each illustrated portion might be different from those of each portion of an actual prober.

Those skilled in the art will recognize that many alternative embodiments can be accomplished using the teachings of the present invention and that the invention is not limited to the embodiments illustrated herein for explanatory purposes.

### First Embodiment

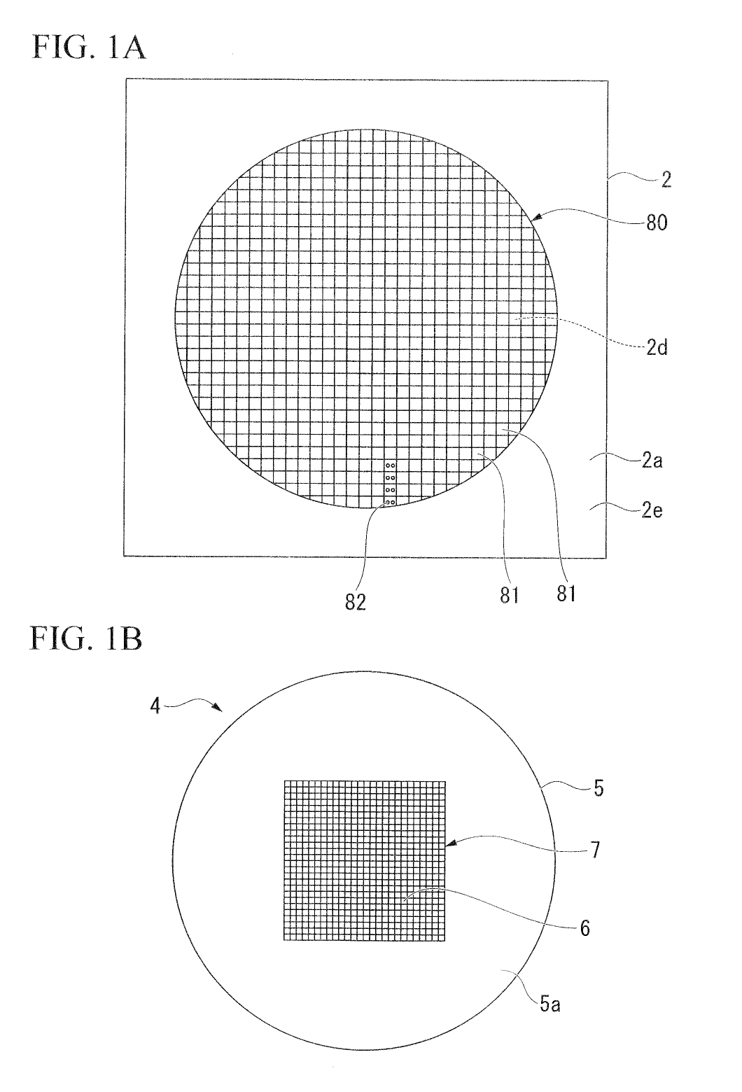

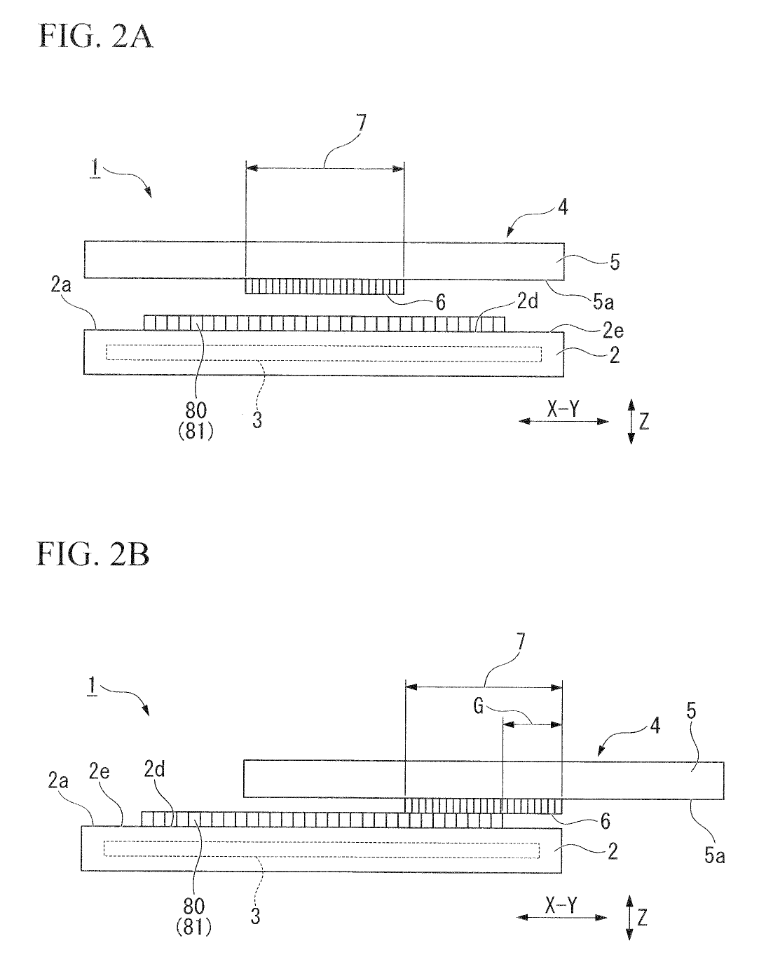

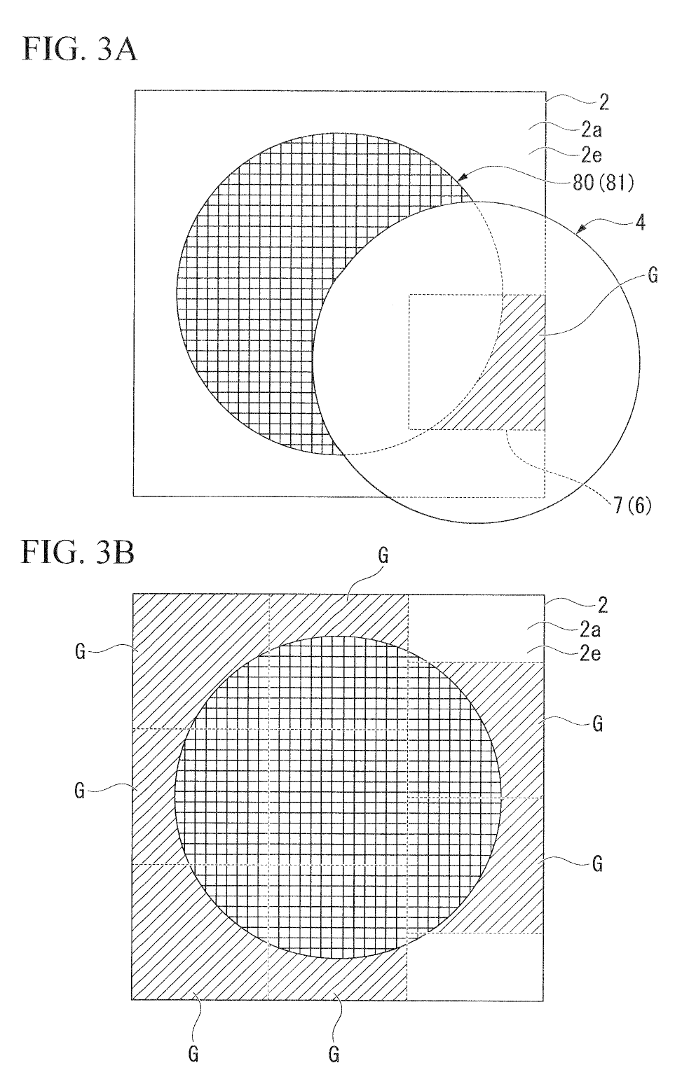

Hereinafter, a prober 1 according to a first embodiment of the present invention is explained with reference to FIGS. 1 to 3. FIG. 1A is a plane view illustrating a wafer 80 mounted on a stage 2 of the prober 1. FIG. 1B is a plane view illustrating a probe card 4 included in the prober 1 viewed from a side of the probe pin 6 (probe area 7). FIGS. 2A and 2B are lateral views of the prober 1. FIGS. 3A and 3B are plane views illustrating a state of the prober 1 testing the wafer 80.

The prober 1 includes: the probe card 4 having probe pins 6; the stage 2 on which the wafer 80 is to be mounted; and a temperature adjuster 3 that adjusts a temperature of the wafer 80 and a peripheral region 2e of the stage 2. The stage 2 is generally square and larger than the circular wafer 80 to be mounted on an upper surface 2a of the stage 2. The prober 1 and a tester (not shown) form a semiconductor wafer testing apparatus.

The wafer 80 whose electric characteristics are to be tested by the prober 1 is formed by, for example, dicing an ingot formed by a crystal growth of a semiconductor into multiple pieces of generally circular wafers, and forming multiple semiconductor chips on each of the wafers. Electric characteristics of the wafer 80 on which multiple semiconductor chips are formed are tested by a semiconductor wafer testing apparatus including the prober 1 and a tester (not shown). Then, the wafer 80 is diced into multiple chips, each of the chips is bonded to lead frames and the like, and thus a semiconductor device is formed.

Then, the prober 1 mounts the wafer 80 on the stage 2, and contacts the probe pins 6 included in the probe card 4 onto electrode pads 82 provided on each chip 81 on the wafer 80. Then, the aforementioned tester supplies power and various test signals to each chip 81 through the probe pins 6. Then, the tester analyzes signals output to the electrode pads 82 of each chip 81 to determine whether or not each chip 81 is defective as an electric characteristics test Such an electric characteristic test is carried out multiple times at different test temperatures.

The stage 2 is for the wafer 80 to be tested being mounted on the upper surface 2a, and made of, for example, a metal material to be conventionally used in this field. The wafer 80 is mounted on the stage 2, and the stage 2 moves in parallel with the probe card 4. The stage 2 includes a wafer region 2d on which the wafer 80 is mounted, and a peripheral region 2e surrounding the wager region 2d. When the probe area 7 of the probe card 4 in which the probe pins 6 are provided deviates from the wafer region 2d, the probe area 7 faces the peripheral region 2e.

The stage 2 is generally square and larger than the circular wafer 80 on the upper surface 2a. The stage 2 can move in the horizontal and vertical directions by an X-Y moving apparatus (not shown) and a Z moving apparatus (not shown) which are made of, for example, motors. When the wafer 80 is tested by the prober 1, the stage 2 with the wafer 80 being mounted on the wafer region 2d moves in the horizontal direction separating from the probe card 4. When the probe pins 6 in the probe area 7 of the probe card 4 faces the target chips 81 on the wafer 80, the stage 2 moves in the vertical direction. Thereby, the electrode pads 82 on each chip 81 to be tested contacts the probe pins 6, and an electric characteristic test can be carried out.

Multiple suction holes (not shown) for mounting the wafer 80 onto the wafer region 2d by vacuum suction are formed in the wafer region 2d of the stage 2. The suction holes connect to a suction apparatus (not shown) to be used for vacuum suction. Thereby, the wafer 80 is fixed on the wafer region 2d of the sage 2 without misalignment when the wafer 80 is to be tested by the prober 1.

The temperature adjuster 3 includes a heating and cooling unit that adjusts a temperature of the wafer 80 mounted on the wafer region 2d and a temperature of the peripheral region 2e. Although not shown, the temperature adjuster 3 includes, for example, a heater for heating the stage 2 and the probe card 4 (probe pins 6), a refrigerant pipe, a temperature sensor for temperature control, and the like. As shown in FIGS. 2A and 2B, the temperature adjuster 3 is included in the stage 2. The prober 1 carries out an electric characteristic test while changing temperatures of the stage 2 and the probe card 4 (probe pins 6) to a given test temperature ranged from, for example, 60 to 125° C. using the temperature adjuster 3.

The probe card 4 includes the probe pins 6 that are provided on a lower surface 5a of a generally circular card 5 and contact the electrode pads 82 on the wafer 80 for detecting electric characteristics of the wafer 80. The probe area 7 of the probe card 4 in which the probe pins 6 are provided is generally square and provided in generally the center of the lower surface 5a of the card 5.

The card 5 is a base of the probe card 4 and may be made of a material conventionally used for a probe card without any change. Although the card 5 included in the probe card 4 is generally circular, the first embodiment is not limited thereto, and the shape of the card 5 may be changed according to that of the prober 1.

The probe pins 6 are provided in the probe area 7 on the lower surface 5a of the card 5 corresponding to an arrangement of electrode pads on the chips 81 on the wafer 80. The probe pins 6 are cantilever or spring lever type, and downwardly extend from the lower surface 5a of the card 5.

The probe pins 6 are arranged corresponding to an arrangement of the electrode pads 82 on the chip 81 so that the multiple chips 81 aligned on the wager 80 in given lines are simultaneously tested. Specifically, if 10 electrode pads 82 are provided on either side of one chip 81, and if 10 chips 81 are to be simultaneously tested, 200 probe pins 6 are aligned in two lines corresponding to the arrangement of the 10 chips 81.

Preferably, a pitch of pinpoints are determined so as to correspond to those of the electrode pads 82 on the wafer 80 when the probe card 4 is heated or cooled to a temperature of the stage 2 and the wafer 80.

The card 5 includes an alignment camera (not shown) for detecting positions of the electrode pads 82 on each chip 81 and adjusting the position of the stage 2 so that the arrangement direction of the electrode pads 82 is identical to that of the probe pins 6. The probe pins 6 are electrically connected to the aforementioned tester through an electrode pattern (not shown).

As shown in FIGS. 2A and 2B, the probe card 4 is placed facing the stage 2 and the wafer 80. Then, the stage 2 can move with respect to the probe card 4 in the horizontal direction (illustrated X-Y direction) and in the vertical direction (illustrated Z direction). The prober 1 is covered by inner walls (not shown) inside of which the wafer 80 is tested.

Hereinafter, a semiconductor wafer testing method using the prober 1 according to the present invention is explained with reference to FIGS. 1 to 3.

First, the wafer 80 to be tested is mounted and fixed on the stage 2 in the wafer region 2d by vacuum suction or the like. Then, the stage 2 is heated or cooled by a heater or a refrigerant pipe (not shown) included in the temperature adjuster 3 so that a temperature of the stage 2 becomes a given test temperature, for example, 60° C.

Then, the stage 2 is horizontally moved by the X-Y moving apparatus (not shown) while the wafer 80 mounted on the stage 2 is separated from the probe card 4. When the probe pins 6 (probe area 7) face the electrode pads 82 on the chips 81, the stage 2 is moved vertically by the Z moving apparatus (not shown). In this case, misalignment of the stage 2 is prevented by the alignment camera (not shown) included in the probe card 4, thereby enabling the probe pins 6 and the electrode pads 82 to precisely contact each other.

Thereby, the electrode pads 82 on the chips 81 and the probe pins 6 are in contact with each other, and then an electronic characteristics test is ready to be carried out.

Then, the tester (not shown) supplies power and various test signals to each of the chips 81 to analyze signals output to the electrode pads 82 on each of the chips 81. Then, an electronic characteristics test is carried out by determining whether or not each chip 81 is defective based on results of the analysis.

Then, the stage 2 is heated or cooled by the temperature adjuster 3 to change a temperature of the wafer 80 to a second test temperature, for example, 80° C. Then, an electronic characteristics test is carried out by determining whether or not each chip 81 is defective in a similar manner.

Thus, electric characteristics tests of the wafer 80 (chips 81) are carried out multiple times at different test temperatures.

After the chips 81 on the same region of the wafer 80 are tested at different temperatures, the stage 2 is vertically moved by the Z moving apparatus so that the probe pins 6 are separated from the electrode pads 81 on the chips 81. Then, the stage 2 is horizontally moved by the X-Y moving apparatus so that the probe pins 6 move to a region targeted for the next test. Then, the stage 2 is vertically moved by the Z moving apparatus so that the probe pins 6 contact the electrode pads 82 on each of the chips 81 in the next targeted region, followed by an electric characteristics test in the same manner.

Then, the above processes are repeated, and electric characteristics tests are sequentially carried out at different target regions.

According to the prober 1 of the first embodiment, the stage 2 includes the peripheral region 2e which faces the probe area 7 when the probe area 7 deviates from the wafer area 2d, as shown in FIG. 2B. Thereby, the probe area 7 in which the probe pins 6 are provided always faces the upper surface 2a of the stage 2, as shown in FIGS. 2B, 3A, and 3B. Therefore, even if a region G of the probe area 7 where the probe pins 6 are not in contact with the electrode pads 82 on the wafer 80 occurs, thermal release from the region G is prevented.

Consequently, the prober 1 can uniformly maintain a temperature of the entire probe card 4, and thereby prevent an occurrence of a temperature distribution of the wafer 80 in contact with the probe pins 6. Therefore, measurement errors caused by a change in a test temperature are prevented, thereby achieving a precise test.

Additionally, the prober 1 can uniformly maintain a temperature of the entire probe card 4, and thereby prevent an occurrence of the difference in, for example, thermal expansion rates between a pitch of the probe pins 6 and a pitch of the electrode pads 82. Therefore, the probe pins 6 can surely contact the electrode pads 82 regardless of test temperatures, enabling a precise detection of electric characteristics of the chips 81 on the wafer 80.

Further, a precise detection of electric characteristics of the chips 81 on the wafer 80 can be achieved by the semiconductor wafer testing method using the prober 1.

### Second Embodiment

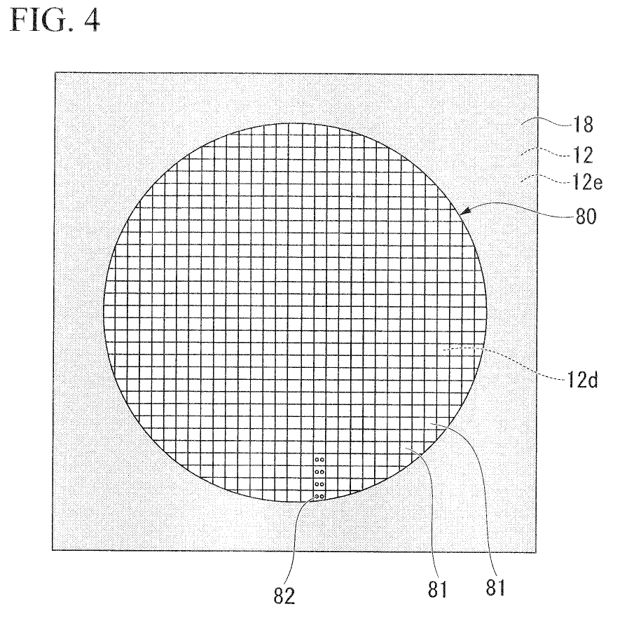

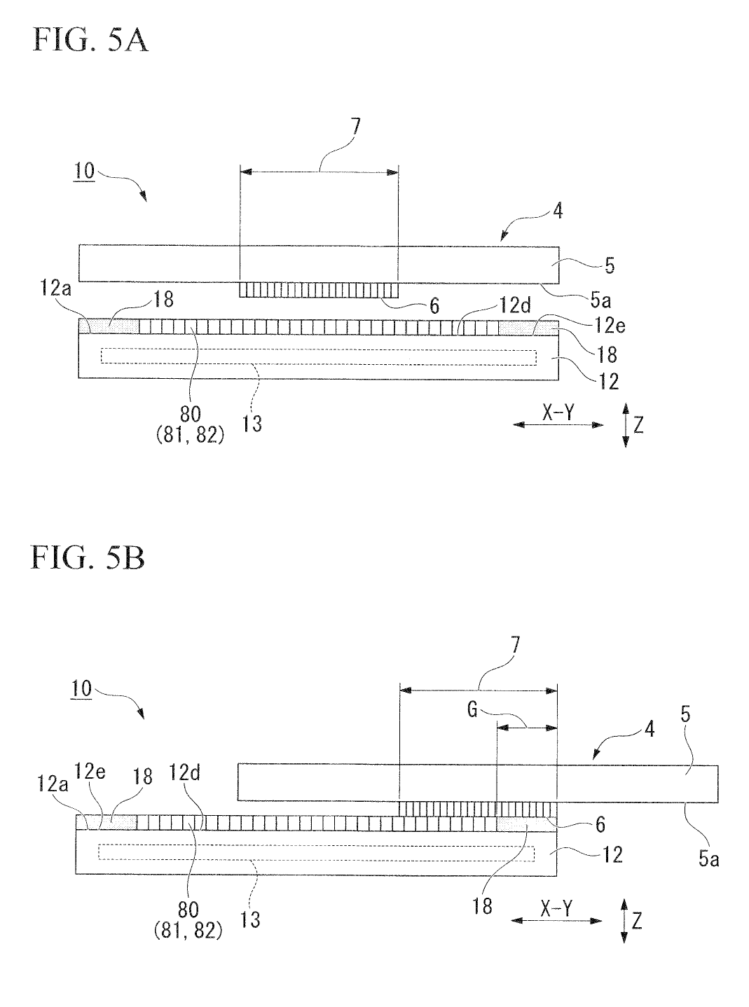

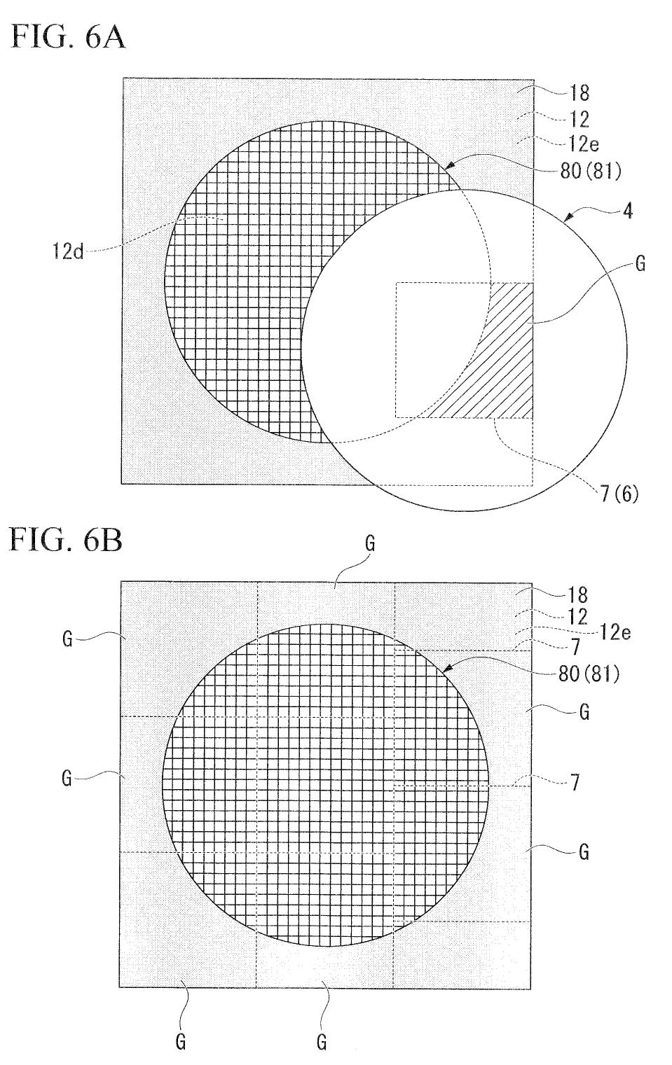

Hereinafter, a prober 10 according to a second embodiment of the present invention is explained with reference to FIGS. 4, 5A, 5B, 6A, and 6B. FIG. 4 is a plane view illustrating the wafer 80 mounted on a stage 12 of the prober 10. FIGS. 5A and 5B are lateral views of the prober 10. FIGS. 6A and 6B are plane views illustrating a state of the prober 10 testing the wafer 80. Like reference numerals denote like elements between the first and second embodiments, and explanations thereof are omitted.

As shown in FIGS. 4, 5A, and 5B, the prober 10 of the second embodiment differs from the prober 1 of the first embodiment in that a sheet 18 is provided on a peripheral region 12e of the upper surface 12a of the stage 12. The sheet 18 has the same thickness as the wafer 80 so that the upper surfaces of the sheet 18 and the wafer 80 forms one surface which will contact the probe pins 6.

Thereby, when the region G of the probe area 7 where the probe pins 6 are not in contact with the electrode pads 82 on the wafer 80 occurs, the region G contact the sheet 18, thereby effectively preventing thermal release from the region G Therefore, a temperature of the entire probe card 4 can be uniformly maintained, thereby preventing an occurrence of a temperature distribution of the wafer 80 in contact with the probe pins 6. Consequently, measurement errors due to a change in a test temperature are prevented, enabling a precise test of the wafer 80 similarly to the first embodiment.

The sheet 18 may be made of, for example, a resin having general thermal resistance, and the material forming the sheet 18 may be appropriately changed. Preferably, the sheet 18 is provided over the entire peripheral region 12e so that the entire region G of the probe area 7 can contact the sheet 18.

Although it is explained in the second embodiment that the sheet 18 is provided on the peripheral region 12e of the stage 12, the second embodiment is not limited thereto. For example, the peripheral region of the stage may be integrated with the stage as a convex region. The similar effects can be achieved as long as a contact surface to be in contact with the probe pins is provided.

### Third Embodiment

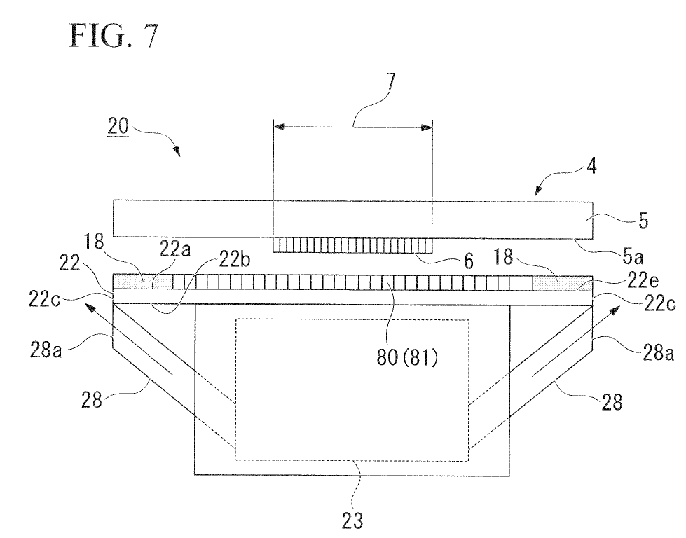

Hereinafter, a prober 20 according to a third embodiment is explained with reference to FIG. 7. FIG. 7 is a lateral view of the prober 20.

The prober 20 differs from the prober 1 of the first embodiment in that a temperature adjuster 23 and a duct 28 through which hot or cold air is supplied to a periphery of the stage 22 are included in the stage 22.

Similar to the prober 1 of the first embodiment, the temperature adjuster 23 includes a heating and cooling unit which is included in the stage 22 and includes a heater and a refrigerant pipe (these are not shown).

The duct 28 has a nozzle-like shape as shown in FIG. 7 such that air can be released from an outlet 28a to an upper surface 22a of the stage 22 (i.e., in an obliquely upward direction in the case of FIG. 7).

A fan (now shown) supplies air heated or cooled by the heater and the refrigerant pipe which are included in the temperature adjuster 23 toward a rim of the stage 22 and the wafer 80 through the duct 28.

According to the prober 20 of the third embodiment, hot or cold air is efficiently supplied toward a rim of the stage 22 through the duct 28. Thereby, a temperature inside the prober 20 surrounded by inner walls (not shown) can be nearly equal to that of the stage 22 and the wafer 80, enabling a temperature of the entire prober 20 to be kept constant. Therefore, a temperature of the entire probe card 4 can be controlled to be nearly equal to that of the wafer 80.

Hot or cold air is not directly supplied to the probe pins 6 through the duct 28, but actually supplied to the card 5 of the probe card 4. Thereby, a temperature of the entire probe card 4 can be easily controlled to be nearly equal to that of the wafer 80.

Accordingly, even if the region G of the probe area 7 where the probe pins 6 are not in contact with the electrode pads 82 on the wafer 80 occurs (see, for example, FIG. 5B), thermal release from the region G is prevented by hot or cold air sent through the duct 28. Thereby, a temperature of the probe card 4 can be uniformly maintained, and an occurrence of a temperature distribution of the wafer 80 in contact with the probe pins 6 is prevented.

Consequently, measurement errors due to a change in a test temperature can be prevented. Thereby, a precise test of the wafer 80 is enabled similarly to the probers 1 and 10 of the first and second embodiments.

Although the sheet 18 is provided on a periphery of the wafer 80 similarly to the prober 10 of the second embodiment, the third embodiment is not limited thereto. In the third embodiment, a temperature inside the prober 20 can be kept constant because of the duct 28 even if the sheet 18 is not provided. Thereby, a temperature of the entire probe card 4 can also be kept constant.

### Fourth Embodiment

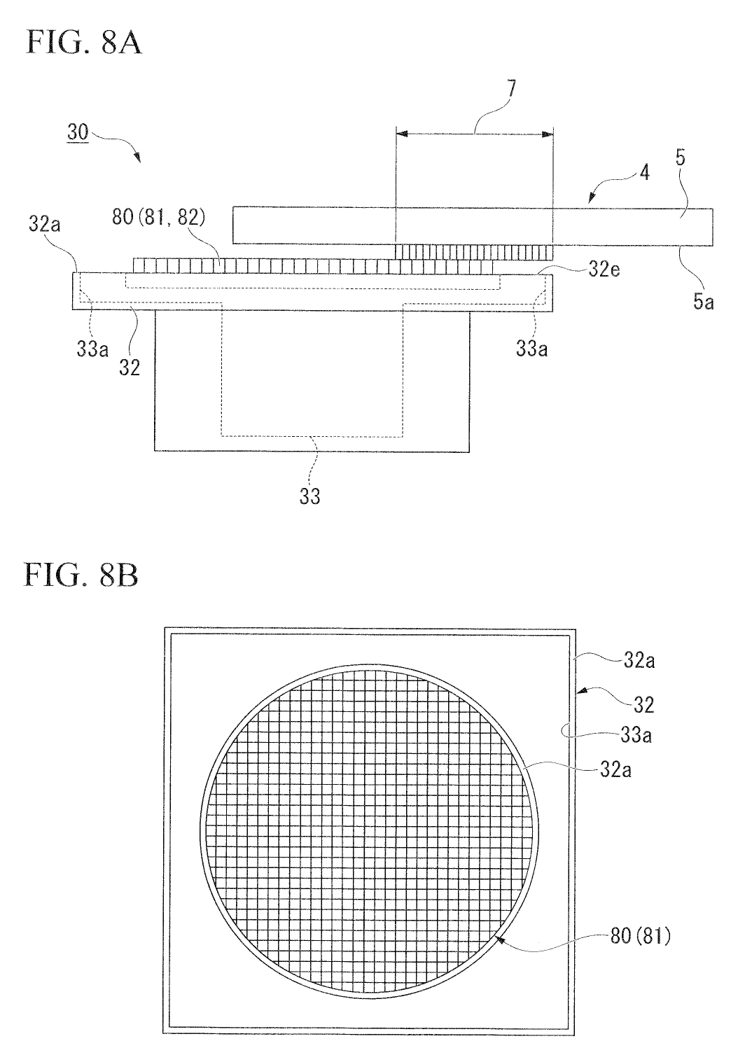

Hereinafter, a prober 30 according to a fourth embodiment of the present invention is explained with reference to FIGS. 8A and 8B. FIGS. 8A and 8B are lateral and plane views of the prober 30, respectively.

The prober 30 differs from the prober 1 of the first embodiment in that a temperature adjuster 33 includes a duct 33a through which hot or cold air is supplied toward a peripheral region 32e of an upper surface 32a of a stage 32.

An outlet of the duct 33a is provided in the peripheral region 32e of the upper surface 32a of the stage 32 so that air can be released toward the upper surface 32a. Specifically, a fan (not shown) supplies air heated or cooled by a heater and a refrigerant pipe which are included in the temperature adjuster 33 through a duct 33a toward the supper surface 32a of the stage 32.

Thereby, the prober 30 can efficiently supply hot or cold air toward the upper surface 32a of the stage 32. Therefore, hot air is directly supplied to the probe card 4 (probe pins 6), and thereby a temperature of the entire probe card 4 can be controlled to be nearly equal to that of the wafer 80.

Additionally, the prober 30 can adjust a temperature inside the prober 30 nearly equal to that of the stage 22 and the wafer 80 so that a temperature of the entire prober 30 can be kept constant.

Accordingly, an occurrence of a temperature distribution of the wafer 80 in contact with the probe pins 6 can be prevented.

According to the prober 30, measurement errors due to a change in a test temperature can be prevented, and a precise test of the wafer 80 is enabled.

### Fifth Embodiment

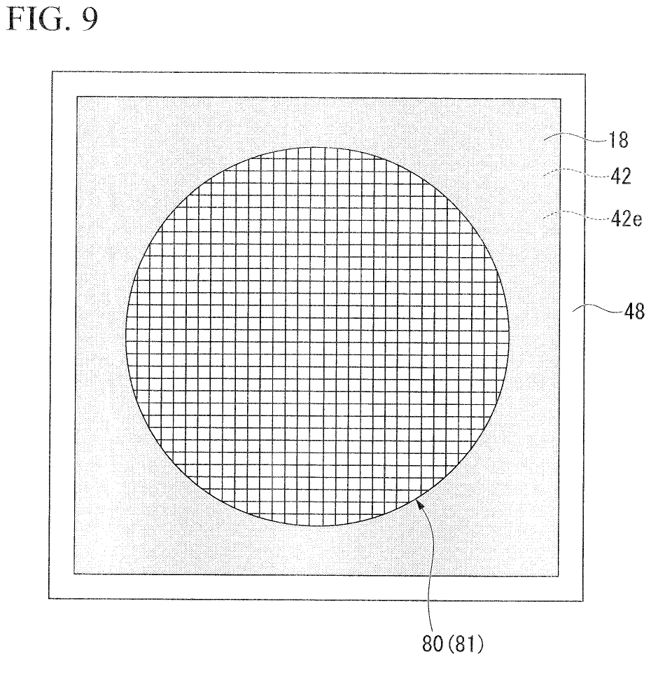

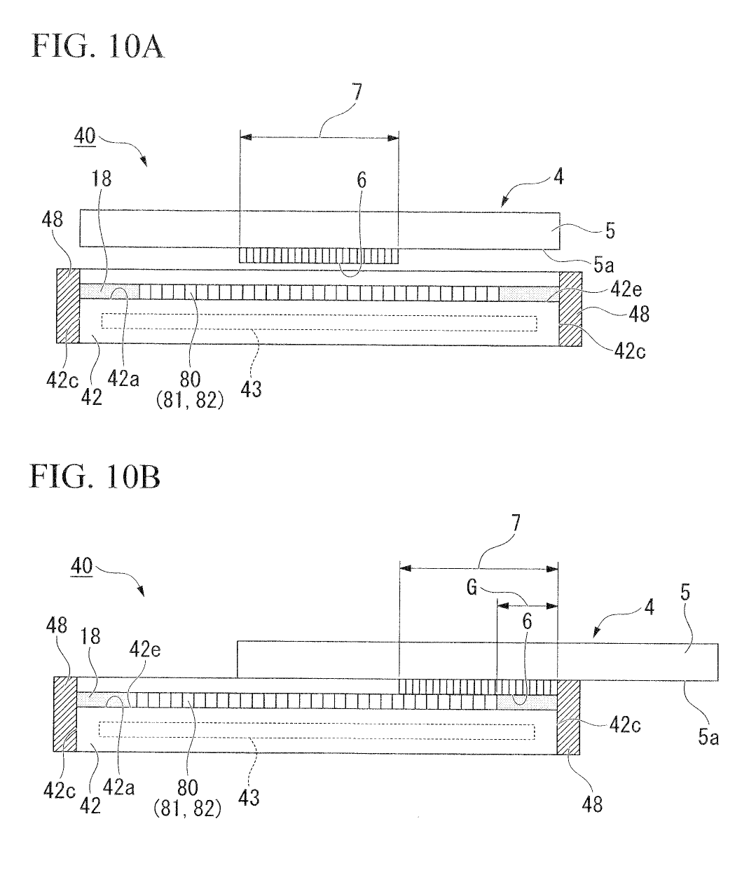

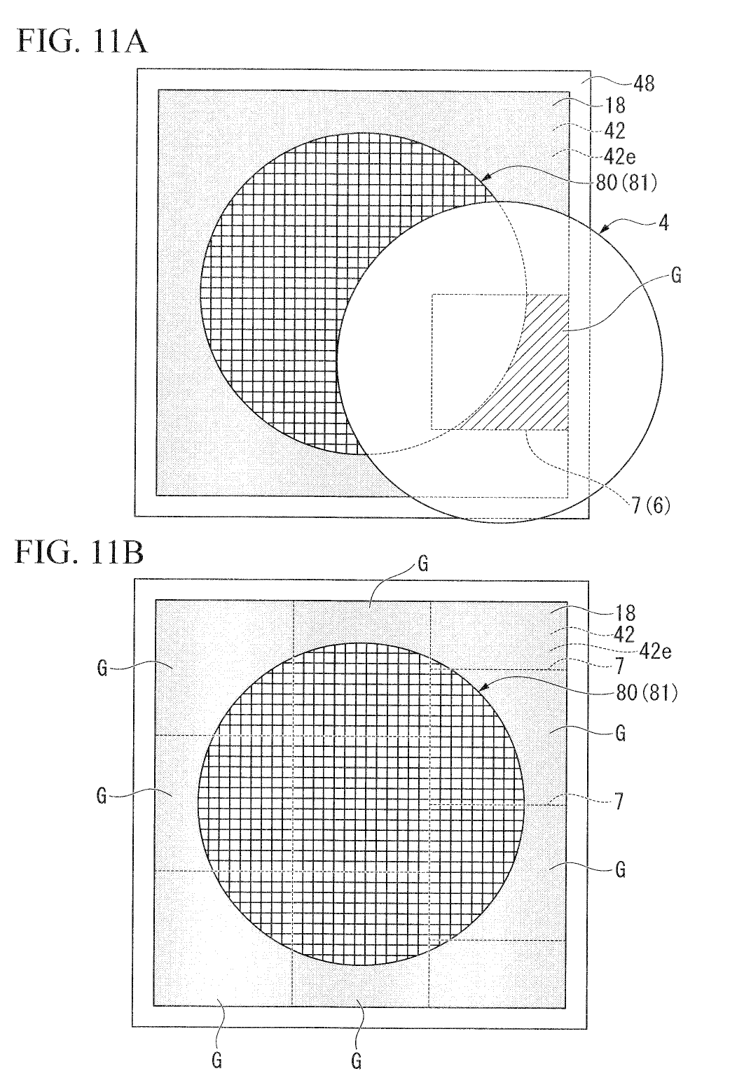

Hereinafter, a prober 40 according to a fifth embodiment of the present invention is explained with reference to FIGS. 9, 10A, 10B, 11A, and 11B. FIG. 9 is a plane view illustrating the wafer 80 mounted on a stage 42 of the prober 40. FIGS. 10A and 10B are lateral views of the prober 40. FIGS. 11A and 11B are plane views illustrating a state of the prober 40 testing the wafer 80.

The prober 40 differs from the prober 1 of the first embodiment in that a sidewall 48 is provided on side surfaces 42c so as to surround an upper surface 42a of a stage 42. Similar to the probers 10 and 20 of the second and third embodiments, the prober 40 includes the sheet 18 on a peripheral region 42e of the wafer 80.

The sidewall 48 may be made of the same material as that forming the stage 42, or of a different material, and a material forming the sidewall 48 may be appropriately changed. The sidewall 48 may be fixed on the stage 42 with screws or the like, or be integrated with the stage 42.

Since the upper surface 42a of the stage 42 is surrounded by the sidewall 48, a temperature distribution of the stage 42 does not occur when the wafer 80 is tested. Thereby, the prober 40 can effectively maintain a temperature of the probe card 4 nearly equal to that of the wafer 80.

When the stage 42 horizontally moves and the probe area 7 reaches the side surface 42c of the stage 42 as shown in FIG. 10B, the probe pin 6 contact the sidewall 48. In this case, heat of the stage 42 is conducted to the probe pins 6 through the sidewall 48. Thereby, a temperature of the probe card 4 becomes nearly equal to that of the stage 42 and the wafer 80.

According to the prober 40, measurement errors due to a change in a test temperature can be prevented, and a precise test of the wafer 80 is enabled.

Although the sheet 18 is provided on the peripheral region 42e of the stage 42 as explained above, the fifth embodiment is not limited thereto. For example, even when the sheet 18 is not provided on the stage 42, a temperature of the stage 42 can be kept constant because of the sidewall 48 in a similar manner. Thereby, a temperature of the entire probe card 4 can be maintained nearly equal to that of the wafer 80.

### Sixth Embodiment

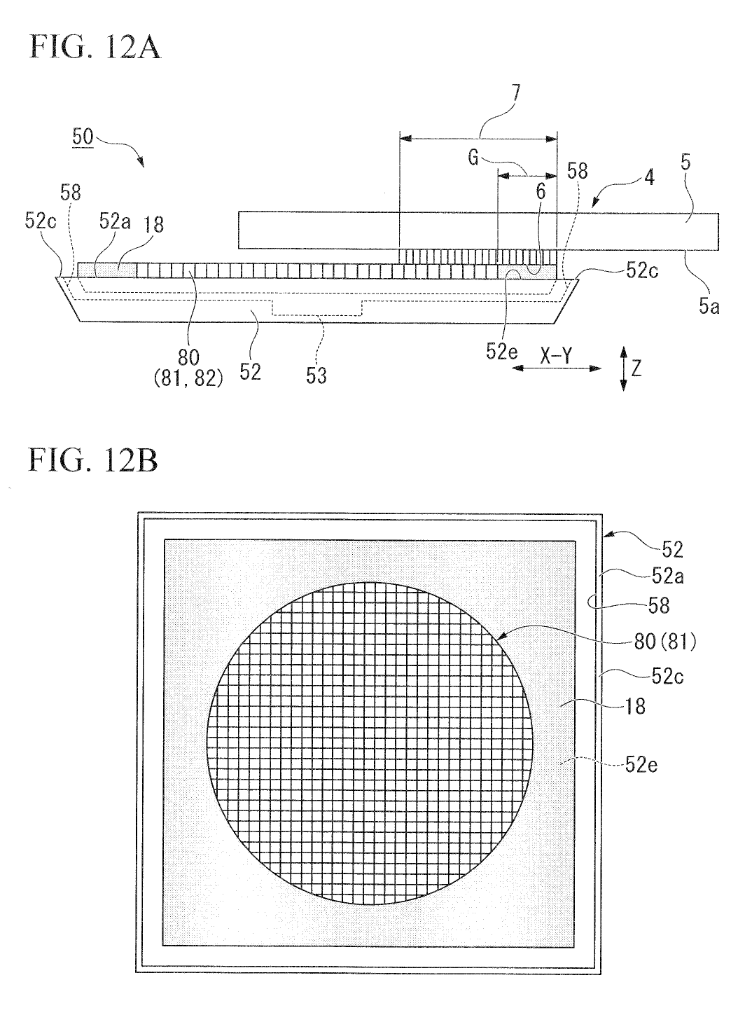

Hereinafter, a prober 50 according to a sixth embodiment of the present invention is explained with reference to FIGS. 12A and 12B. FIGS. 12A and 12B are lateral and plane views of the prober 50, respectively.

The prober 50 differs from the prober 1 of the first embodiment in that a temperature adjuster 53 includes a duct 58 through which hot or cold air is supplied toward an upper surface 52a of the stage 52.

An outlet of the duct 58 is provided in a peripheral region 52c of the stage 52 such that air can be released through the duct 58 toward the upper surface 52a of the stage 52. Specifically, a fan (not shown) supplies air heated or cooled by a heater and a refrigerant pipe which are included in the temperature adjuster 53 through the duct 58 toward the upper surface 52a of the stage 52.

Thereby, hot or cold air can be efficiently supplied toward the periphery of the wafer 80. Therefore, hot or cold air is directly supplied toward the probe card 4 (probe pins 6). Thereby, a temperature of the entire probe card 4 can be maintained nearly equal to that of the wafer 80 similarly to the prober 30 of the fourth embodiment. Similarly, a temperature inside the prober 50 can be nearly equal to that of the stage 52 and the wafer 80, and thereby a temperature of the prober 50 can be kept constant. Accordingly, an occurrence of a temperature distribution of the wafer 80 in contact with the probe pins 6 is prevented.

According to the prober 50, measurement errors due to a change in a test temperature can be prevented, and a precise test of the wafer 80 is enabled.

Although the sheet 18 is provided on the peripheral region 52e of the stage 52 in the case of FIGS. 12A and 12B, the sixth embodiment is not limited thereto. Even when the sheet 18 is not provided, similar effects can be obtained.

### Seventh Embodiment

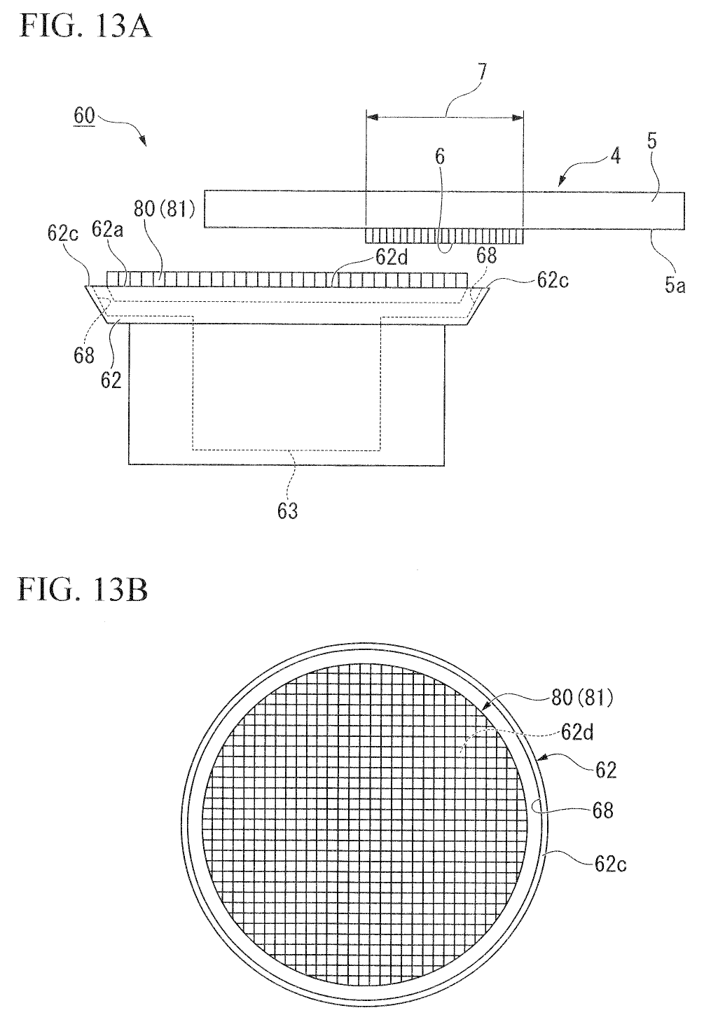

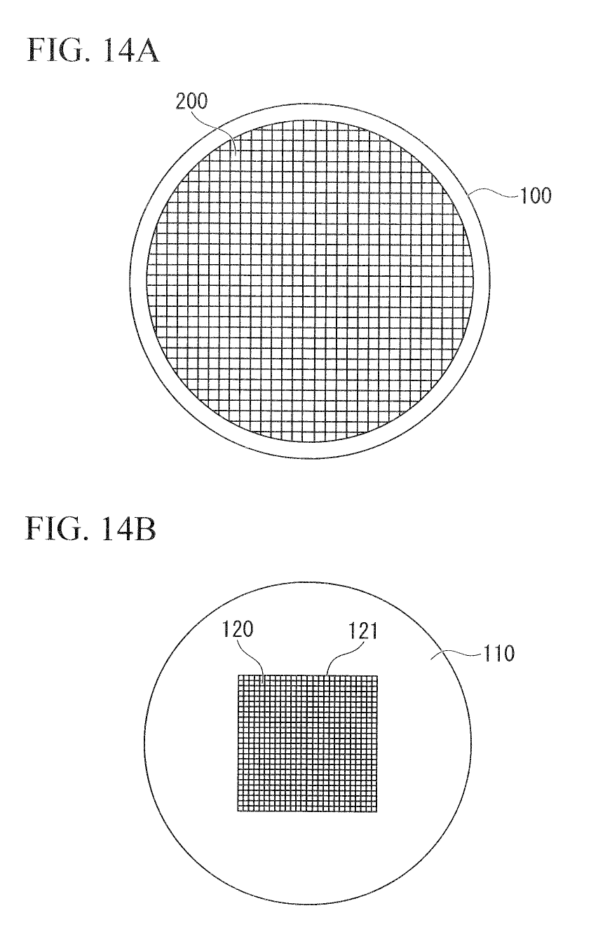

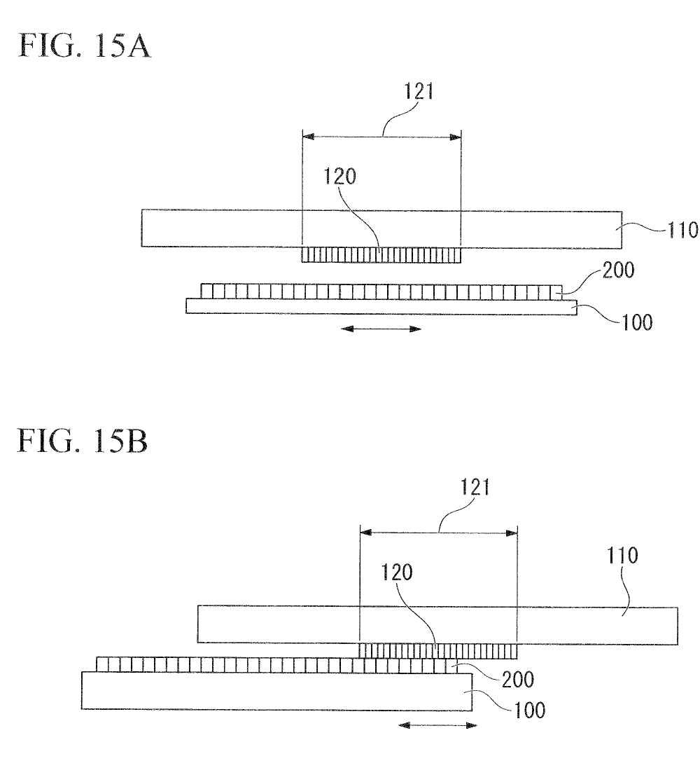

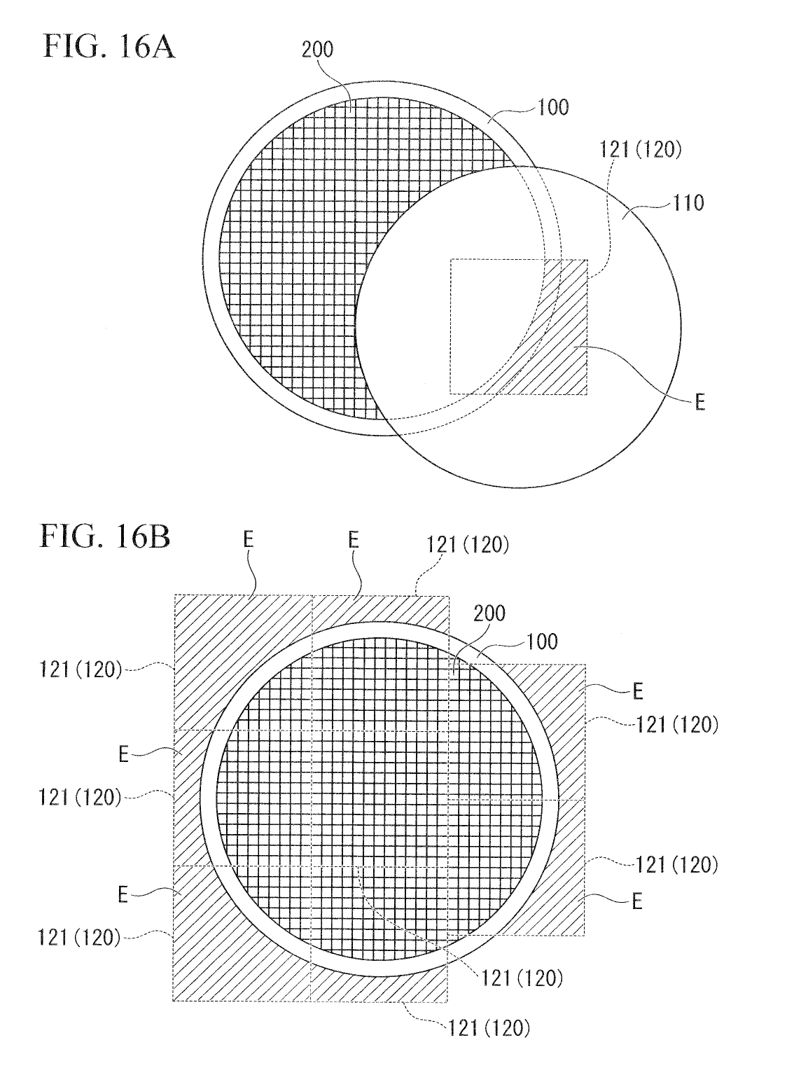

Hereinafter, a prober 60 according to a seventh embodiment of the present invention is explained with reference to FIG. 13. FIGS. 13A and 13B are lateral and plane views of the prober 60, respectively.

The prober 60 includes: the probe card 4 having the probe pins 6; a stage 62 on which the wafer 80 is mounted in a wafer region 62d and which includes a duct 68 whose outlet surrounds the wafer region 62d; and a temperature adjuster 63 that supplies hot or cold air through the duct 68.

The prober 60 differs from the prober 1 in that the outlet of the duct 68 surrounds the wafer region 62d of the stage 62. Specifically, a fan (not shown) supplies air heated or cooled by a heater and a refrigerant pipe which are included in the temperature adjuster 63 through the duct 68 toward the upper surface 62a of the stage 62. Because of the outlet of the duct 68, the hot or cold air can be supplied to a periphery of the wafer 80.

Similar to the prober 60 of the sixth embodiment, the prober 60 can supply hot or cold air directly to the probe card 4 (probe pins 6). Thereby, the prober 60 can maintain a temperature of the entire probe card 4 nearly equal to that of the wafer 80. Additionally, the prober 60 can maintain a temperature inside of the prober 60 nearly equal to that of the stage 62 and the wafer 80, and thereby keep a temperature of the entire prober 60 constant. Therefore, an occurrence of a temperature distribution of the wafer 80 in contact with the probe pin 6 can be prevented.

Accordingly, measurement errors due to a change in a test temperature can be prevented, and a precise test of the wafer 80 is enabled. Additionally, an outlet of the duct 68 surrounds the wafer area 62d of the stage 62, thereby preventing the stage 62 from being larger, and therefore preventing the entire prober 60 from being larger.

As explained above, according to the probers of the present invention, even if a region of the probe area 7 where the probe pins 6 are not in contact with the electrode pads 82 on the wafer 80 occurs, thermal release from the region can be prevented. Thereby, a temperature of the entire probe card 4 can be kept constant, and an occurrence of a temperature distribution of the wafer 80 can be prevented. Thereby, measurement errors due to a change in a test temperature can be prevented. Additionally, the difference in pitches between the probe pinpoints 6 and the electrode pads 82 does not differ, and therefore the probe pins 6 can contact the electrode pads 82 regardless of a change in a test temperature. Accordingly, electric characteristics of the wafer 80 can precisely be detected without errors.

Further, the semiconductor wafer testing method of the present invention uses the prober of the present invention, and therefore electric characteristics of a wafer can precisely be detected without errors.

It is apparent that the present invention is not limited to the above embodiments, but may be modified and changed without departing from the scope and spirit of the invention.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to a device equipped with the present invention.

What is claimed is:

1. A prober for a semiconductor wafer test, comprising:
a stage having a first region and a second region other than the first region the first region being covered by a wafer on which a plurality of electrode pads is provided;
a probe card comprising a plurality of probe pins to be in contact with the plurality of electrode pads; and
an adjuster that is included in the stage and adjusts a temperature of the wafer and the second region.

2. The prober according to claim 1, further comprising:
a sheet that covers the second region and has the same thickness as that of the wafer.

3. The prober according to claim 1, further comprising:
a sidewall immediately surrounding an outer rim of the stage, the sidewall being in contact with the outer rim of the stage.

4. The prober according to claim 1, further comprising:
a sidewall immediately surrounding an outer rim of the stage, the sidewall being in contact with the outer rim of the stage; and
a sheet that covers the second region and has the same thickness as that of the wafer.

5. The prober according to claim 1, wherein a height of the sidewall is greater than that of a combination of the stage and the wafer.

6. The prober according to claim 1, wherein
the adjuster comprises:
a fan that supplies air; and
a heating and cooling unit that at least heats or cools the air.

7. The prober according to claim 6, wherein the adjuster comprises an air duct extending toward an outer rim of the stage, the air duct having an outlet facing obliquely upward.

8. The prober according to claim 6, wherein the adjuster comprises an air duct having an outlet within the second region.

9. The prober according to claim 6, further comprising:
a sheet that covers the second region, immediately surrounds the wafer, and has the same thickness as that of the wafer,
wherein the adjuster comprises an air duct having an outlet within the second region, the outlet surrounding the sheet.

10. The prober according to claim 6, wherein the adjuster comprises an air duct having an outlet within the second region, the outlet surrounding an outer rim of the wafer.

11. The prober according to claim 1, wherein the probe card comprises an alignment camera for adjusting a position of the plurality of probe pins with respect to a position of the plurality of electrode pads.

12. A method of testing a semiconductor wafer, comprising:
moving a probe card in parallel with a stage having a first region and a second region other than the first region, the semiconductor wafer covering the first region;
adjusting a position of a plurality of probe pins on the probe card with respect to a position of a plurality of electrode pads on the semiconductor wafer;
contacting at least one of the plurality of probe pins onto at least one of the plurality of electrode pads; and
adjusting a temperature of the semiconductor wafer and the second region.

13. The method according to claim 12, wherein adjusting the temperature comprises supplying hot or cold air toward the second region through an air duct extending from an adjuster, the air duct and the adjuster being included in the stage.

14. The method according to claim 13, wherein the air duct has an outlet facing obliquely upward.

15. The method according to claim 13, wherein the air duct has an outlet within the second region.

16. The method according to claim 13, wherein the air duct has an outlet within the second region, the outlet surrounding an outer rim of the wafer.
